(19) United States
(12) Patent Application Publication
(10) Pub. No.: US 2006/0193184 A1
(43) Pub. Date: Aug. 31, 2006

(54) Hub module for connecting one or more memory chips

(76) Inventor: Peter Poechmueller, Dresden (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/348,514

(22) Filed: Feb. 6, 2006

Related U.S. Application Data
(63) Continuation of application No. PCT/EP04/08748, filed on Aug. 4, 2004.

(30) Foreign Application Priority Data
Aug. 5, 2003 (DE) DE 103 35 708.4

(51) Int. Cl. G11C 29/00

(52) U.S. Cl. 365/200

(57) ABSTRACT

The invention relates to a hub module for connecting one or more memory chips, said module having an address input for connection to an address bus in order to receive an address of the memory area to be addressed and having an address output for connection to a further address bus, and having an address decoder unit in order to address one of the connected memory chips using an address that is applied to the address input or to apply the applied address to the address output, characterized in that the address decoder unit has a redundancy unit in order to address a redundant memory area instead of the addressed memory area in the event of a defect being detected in a memory area of the one or more connected memory chips.

### CROSS-REFERENCE TO RELATED APPLICATIONS

This application is a continuation of co-pending PCT patent application No. PCT/EP 2004/008748, filed Aug. 4, 2004, which claims the benefit of German patent application serial number DE 103 35 708.4, filed Aug. 5, 2003. Each of the aforementioned related patent applications is herein incorporated by reference in its entirety.

### BACKGROUND OF THE INVENTION

1. Field of the Invention

The invention relates to a hub module for connecting one or more memory chips for use in a memory module.

2. Description of the Related Art

Memory chips are frequently used in personal computers to store data which are to be processed in the personal computer. For this purpose, the memory chips are combined to form memory modules in order to satisfy the requirements for a high storage capacity. In order to use the storage capacity of a plurality of memory modules, provision is usually made of an address and data bus, to which the memory modules are connected, that is to say, each of the memory modules is connected to the common address and data bus. On account of the line and input capacitances of the corresponding inputs for the address and data bus on the memory modules and on account of the signals being reflected at branches, the maximum clock frequency at which address data and useful data can be transmitted is limited.

When using double data rate (DDR) technology, in particular, the frequencies at which data have to be transmitted via the address and data bus may be very high. It is therefore appropriate, for future DDR III or other high-performance interface technology, not to operate the memory modules using a common address and data bus.

One possible alternative address and data bus concept involves providing a so-called hub module between a memory controller in the personal computer and the memory chips, said module being utilized to drive one or more memory chips. The hub module is connected to the memory controller that controls the storage and retrieval of data. The hub module has an input for the address and data bus in order to receive address data and useful data and possibly to transmit useful data to the memory controller. The hub module also has an output, via which the address and useful data are output. The output for the address and useful data may be connected to an input of a further downstream hub module, to which memory chips are in turn connected.

The hub module has an address decoder unit, which receives the applied address and, in a manner dependent on the address, either addresses one of the connected memory chips or applies the applied address to the address output so that it can be forwarded to the next hub module. In a corresponding manner, the useful data which are applied to the data bus are either forwarded or written to the connected memory chips.

On account of the production technology, memory chips cannot be produced without defects. Defects which occur are repaired at the chip level in a plurality of steps both in a wafer repair step and possibly in a back-end repair step. Nevertheless, it may happen that further defects which were previously not detected can occur in the memory chips which have been repaired in this manner (for example memory cell degradation after a relatively long time in operation). These defects may result in the computer system no longer operating in a stable manner or in the possibility of defects occurring when executing software.

### SUMMARY OF THE INVENTION

It is an object of the present invention to provide a hub module, which makes it possible for a computer system to be operated despite the occurrence of defects in the memory chips used.

The invention provides a hub module for connecting one or more memory chips each having at least one memory area. The hub module has an address input for connection to an address bus in order to receive an address of a memory area to be addressed and has an address output for connection to a further address bus. An address decoder unit is provided in order to address a memory area of one of the connected memory chips using an address that is applied to the address input or to apply the applied address to the address output. The address decoder unit has a redundancy unit in order to address a redundant memory area instead of the addressed memory area in the event of a defect being detected in a memory area of the one or more connected memory chips.

A redundancy unit is thus provided in the hub module according to the invention in order to address a memory area that is provided in redundant fashion instead of a regular memory area when a defect occurs. This makes it possible, after the memory chips have been produced completely, have been tested and have been repaired in the wafer repair step and the back-end repair step, for the memory chips to be operated even if a defect occurs in the memory chips. If, for example, one or more memory areas in the memory chips in a memory module fail on account of defects, it is thus subsequently possible to change the memory module (without manipulating the memory chip in question or the memory controller used) in such a manner that it can still be operated in the computer system. This is possible by providing the hub module with a redundancy unit that makes it possible to repair the defect.

Provision may be made for the address decoder unit to have a defect address input in order to receive a defect address. The address decoder unit comprises a comparator unit in order to compare the defect address with the applied address and to address a further redundant memory area instead of the addressed memory area in the event of identity being ascertained between the defect address and the applied address. To this end, a defect address memory may preferably be provided in order to store the defect address and to provide the address decoder unit with said defect address.

The redundant memory area may be provided in the connected memory chips, or provision may be made of an additional memory chip that comprises the redundant memory area. Alternatively, the hub module may comprise the redundant memory area. This makes it possible to provide, in a simple manner, a repair possibility for a memory module that is provided with only one hub module with a redundant memory area. The memory chips or the memory controller need not be changed for this. Another aspect of the present invention provides a memory module having a hub module and connected memory chips.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a block diagram of a memory system having memory modules with hub modules according to a first embodiment of the invention; and

FIG. 2 shows a memory system having memory modules with hub modules according to a second embodiment.

### DETAILED DESCRIPTION OF THE PREFERRED EMBODIMENT

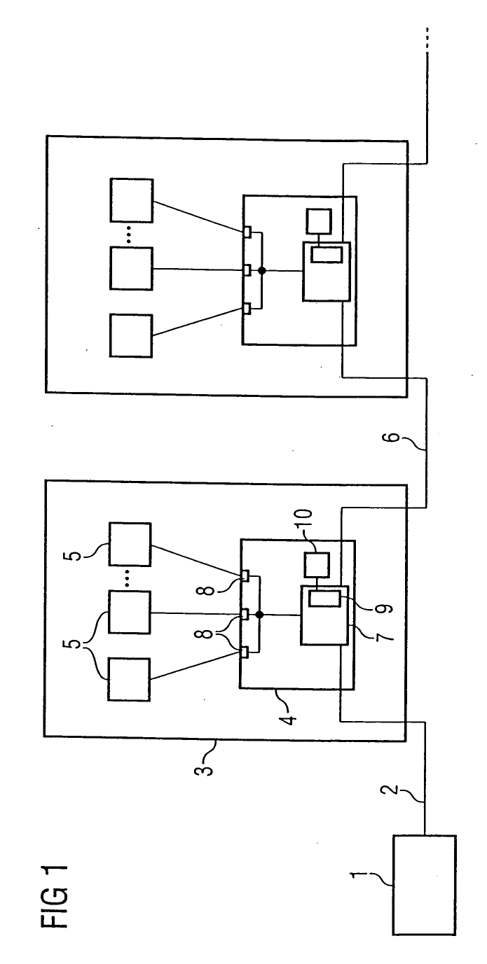

FIG. 1 illustrates a memory system, for example, for a computer system. The memory system has a memory controller 1, to which an address bus 2 having a number n of address lines is connected. The memory controller 1 is capable of driving memory chips with the aid of a DDR memory protocol, for example. The address lines are connected to an input of a memory module 3. The memory module 3 has a hub module 4, to which one or more memory chips 5 are connected. The memory chips are preferably DDR memory chips, particularly DDR DRAM memory chips. The address input of the memory module 3 is connected to an address input of the hub module 4. The hub module 4 has an address output that is connected to a further address bus 6 via the address output of the memory module 3. The further address bus 6 is connected to an address input of a further memory module.

The hub module has an address decoder unit 7, which checks the addresses which are applied to the address bus 2 and, depending on the applied address, addresses the corresponding connected memory chip 5 via a respective memory chip interface 8 or forwards the applied address to the further address bus 6. From the further address bus 6, the address is then received by the address decoder unit of the hub module of the next memory module and, in the same manner, is either used there to address one of the connected memory chips 5 or is forwarded to another further address bus via the address output.

Instead of providing an individual memory chip interface 8 for each of the connected memory chips 5, it is also possible to provide a common memory chip interface 8 that is connected to all of the connected memory chips 5 via a module-internal address and data bus. Memory chip interfaces 8 which are separate from one another have the advantage that the memory chips 5 can be addressed essentially in a parallel manner or at a relatively high speed, while, in the case of a memory chip interface that is designed to be common, the outlay on wiring can be reduced.

The address decoder unit 7 of the hub module 4 also has a redundancy unit 9, which is used to perform address mapping, that is to say, to internally replace an applied address that addresses a defective memory area with another address so that the defective memory area is replaced with a redundant memory area. To this end, the addresses for the defective memory areas are stored in the redundancy unit and said defective memory areas are each assigned a further redundant memory area that is intended to replace the defective memory area. The defect addresses are determined by testing the memory chips at the memory module level and are determined either by means of a test function that is integrated in the hub module or by means of an external test function. The defect addresses may be provided in the defect address memory 10 with the aid of laser fuses or electrical fuses on the hub chip or with the aid of an external source, for example an EPROM, on the hub chip. The memory areas of the memory chips 5 are divided into a first regular memory area part and a second redundant memory area part. The manner in which the memory areas are divided is arbitrary and is essentially determined by the address decoder unit 7 of the hub module 4. Redundant memory areas may thus be provided in each of the memory chips 5. Alternatively, provision may also be made for redundant memory areas for replacing the defective memory areas of all of the connected memory chips 5 to be provided in only one of the connected memory chips 5.

The regular and the redundant memory areas in the sense of this invention do not correspond to the regular memory areas and the redundant memory areas in a memory chip as occur during the wafer repair method and the back-end repair method. The regular and redundant memory areas in one of the memory chips 5 represent only a logical organization of the memory areas (which have been tested and found to be operational) in the memory chips 5. Both regular and redundant memory areas in the sense of the invention correspond to the memory areas (which have been tested and found to be free of defects) in the respective memory chips 5.

The redundancy unit 9 may comprise a defect address memory 10 or may be connected to a defect address memory 10 that is likewise provided in the hub module 4 or is externally provided. The defect address memory 10 is used to store defect addresses which specify which of the applied addresses must be assigned to a redundant memory area since the regular memory area at the applied address is defective. To this end, the redundancy unit 9 preferably has a comparator unit (not shown) that compares the applied address with the defect addresses stored in the defect address memory 10 and addresses the corresponding regular memory area that is addressed in accordance with the address or the redundant memory area in one of the connected memory chips 5 depending on whether or not a defect has been detected.

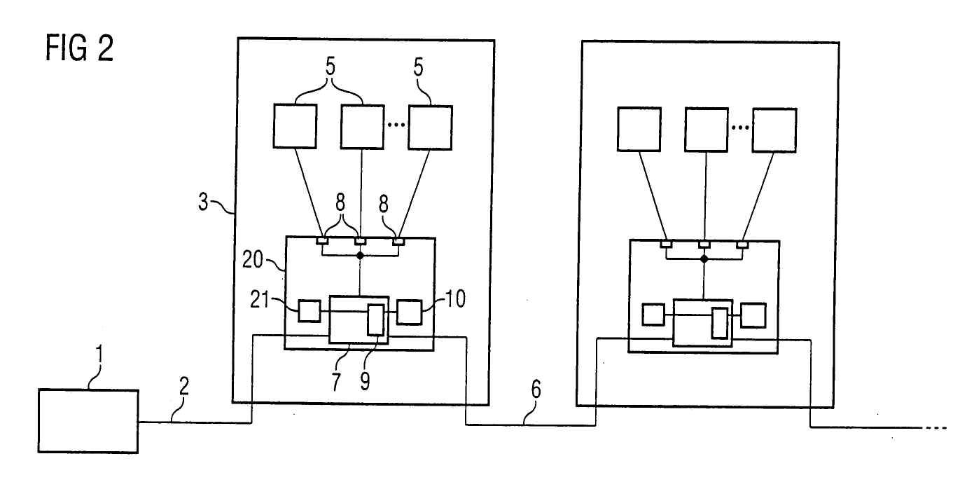

FIG. 2 illustrates a further embodiment of a hub module according to the invention. In addition to the redundancy unit 9, the hub module 20 has redundant memory areas 21 which are integrated in the hub module 20. This makes it possible to avoid providing additional memory chips 5 having redundant memory areas which must be connected to the hub modules 20. Since the failure rate of memory areas is usually very low after the memory chips 5 have been tested, it is possible to provide redundant memory areas 21 in the hub module 20 so that it is possible to rapidly access the redundant memory areas 21. The additional redundant memory areas 21 may be provided in the address decoder unit 7 or at another location in the hub module 20.

The additional redundant memory areas 21 may be connected to the data bus (which is not shown and is connected to the memory module 3) via a multiplexer (not shown) in order to transmit the useful data if an address that is to be replaced with a redundant memory area is applied to the address bus 2.

While the foregoing is directed to embodiments of the present invention, other and further embodiments of the invention may be devised without departing from the basic scope thereof, and the scope thereof is determined by the claims that follow.

What is claimed is:

1. A hub module for connecting one or more memory chips, comprising:
an address input for connection to an address bus to receive an address of a memory area to be addressed;
an address output for connection to a further address bus; and
an address decoder unit configured to selectively address one of the connected memory chips using the address applied to the address input and apply the address to the address output, the address decoder unit comprising:
a redundancy unit configured to address a redundant memory area instead of the addressed memory area when a defect is detected in the addressed memory area of the one or more connected memory chips.

2. The hub module of claim 1, wherein the address decoder unit further comprises:
a defect address input configured to receive a defect address; and
a comparator unit configured to compare the defect address with the applied address and to address a respective redundant memory area instead of the addressed memory area when the defect address is identical to the applied address.

3. The hub module of claim 2, further comprising:
a defect address memory configured to store the defect address and to provide the defect address to the address decoder unit.

4. The hub module of claim 2, wherein the redundant memory area is provided in the connected one or more memory chips.

5. The hub module of claim 2, wherein the redundant memory area is integrated into the hub module.

6. The hub module of claim 3, wherein the redundant memory area is provided in the connected one or more memory chips.

7. The hub module of claim 3, wherein the redundant memory area is integrated into the hub module.

8. The hub module of claim 1, wherein the hub module is integrated into a memory module having a plurality of memory chips.

9. The hub module of claim 1, wherein the address input is connected to a memory controller via the address bus.

10. A memory system, comprising:
a memory controller;
one or more memory modules; and
an address bus connected between the memory controller and the one or more memory modules;
wherein each memory module comprises:
one or more memory chips; and
a hub module connected to the one or more memory chips, the hub module comprising:
an address input connected to the address bus for receiving an address of a memory area to be addressed;
an address output for connection to a further address bus; and
an address decoder unit configured to selectively address one of the one or more memory chips using the address applied to the address input and apply the address to the address output, the address decoder unit comprising a redundancy unit configured to address a redundant memory area instead of the addressed memory area when a defect is detected in the addressed memory area of the one or more connected memory chips.

11. The memory system of claim 10, wherein the address decoder unit further comprises:
a defect address input configured to receive a defect address; and
a comparator unit configured to compare the defect address with the applied address and to address a respective redundant memory area instead of the addressed memory area when the defect address is identical to the applied address.

12. The memory system of claim 10, wherein the hub module further comprises:
a defect address memory configured to store the defect address and to provide the defect address to the address decoder unit.

13. The memory system of claim 12, wherein the redundant memory area is provided in the one or more memory chips.

14. The memory system of claim 12, wherein the redundant memory area is integrated into the hub module.

15. The memory system of claim 10, wherein the one or more memory modules comprises a first memory module and second memory module connected in series, and wherein the address input of the hub module of the first memory module is connected to the memory controller via the address bus and the address output of first memory module is connected to the address input of the hub module of the second memory module via the further address bus.

16. A memory module, comprising:
one or more memory chips; and
a hub module connected to the one or more memory chips, the hub module comprising:
an address input for connection to an address bus for receiving an address of a memory area to be addressed;
an address output for connection to a further address bus; and
an address decoder unit configured to selectively address one of the one or more memory chips using the address applied to the address input and apply the address to the address output, the address decoder unit comprising a redundancy unit configured to address a redundant memory area instead of the addressed memory area when a defect is detected in the addressed memory area of the one or more connected memory chips.

17. The memory module of claim 16, wherein the address decoder unit further comprises:
a defect address input configured to receive a defect address; and
a comparator unit configured to compare the defect address with the applied address and to address a respective redundant memory area instead of the addressed memory area when the defect address is identical to the applied address.

18. The memory module of claim 17, wherein the hub module further comprises:
a defect address memory configured to store the defect address and to provide the defect address to the address decoder unit.

19. The memory module of claim 18, wherein the redundant memory area is provided in the one or more memory chips.

20. The memory system of claim 18, wherein the redundant memory area is integrated into the hub module.
